(19) United States
(12) Patent Application Publication
(10) Pub. No.: US 2006/0093753 A1
(43) Pub. Date: May 4, 2006

(54) Method of engineering a property of an interface

(76) Inventor: Janice H. Nickel, Sunnyvale, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/977,382

(22) Filed: Oct. 29, 2004

(51) Int. Cl. C23C 14/00; B05C 11/00; C23C 16/00

(52) U.S. Cl. 427/523; 118/723 FI; 118/697

(57) ABSTRACT

A method of engineering a property of an interface using a gas cluster ion beam (GCIB) apparatus is disclosed. The method includes introducing a metal-organic compound with a carrier gas to form a metal-organic gas and mixing the metal-organic gas with a cluster gas used in the GCIB. The GCIB forms a plurality of gas cluster ions that include the metal-organic compound, focuses the gas cluster ions into a beam, and then accelerates the beam towards an interface surface of a target material where the gas cluster ions impact on the interface surface and at least a portion of the metal-organic compound remain in contact with the interface surface and modifies a property of the interface surface. The metal-organic gas can include a plurality of metal-organic compounds.

### FIELD OF THE INVENTION

The present invention relates generally to a method of engineering a property of an interface using a gas cluster ion beam apparatus and a metal-organic generator. More specifically, the present invention relates to a method of engineering a property of an interface by using a gas cluster ion beam apparatus and a source for generating a metal-organic compound in combination with each other to produce an ionized gas cluster beam that includes any of a variety of elements that can be produced from a metal-organic compound precursor.

### BACKGROUND ART

Interface effects are becoming increasingly more important in device engineering. Examples of devices that depend on precise control of an interface between adjacent layers of thin film materials include sensors, semiconductor devices, photonic devices, MEMS devices, and magnetoresistance devices (e.g. MRAM). Generally, as devices geometries become smaller, interface properties becomes a larger consideration in the device. Basically, the surface to volume ratio increases as device size decreases. As a result, controlling the interface properties of many types of devices will become more important.

Precise control of interface states is at present difficult to accomplish. Interface topography and composition are nearly impossible to control and prior methods have only allowed gross manipulation of interface properties. A surface roughness of an interface can be modified using ion etching or by using a gas cluster ion beam (GCIB) bombardment process. As device sizes decrease, undesirable surface anomalies at an interface are a major obstacle to producing devices with an economically acceptable yield. Examples of those anomalies include surface roughness, asperities, and lattice mismatch. Further, surface roughness can begin to be on the order of a thickness of a layer of film that will be subsequently deposited on the interface.

Presently, one can try to prevent surface anomalies at an interface by deposition in an ultra high vacuum system; however, the use of the ultra high vacuum system results in high manufacturing costs and low manufacturing throughput. Moreover, making compositional interface layers requires using conventional deposition techniques to deposit various materials that will comprise the layers. However, for very thin layers of materials, uniform coverage is very difficult depending on the wetting characteristics of the material of the underlying layer. For instance, many materials tend to form islands when deposited, which coalesce and grow, resulting in either a non-uniform layer or in a non-uniform topographical surface that is many monolayers thick. Additionally, lattice mismatched materials create strain at the interface between thin film layers and the strain can result in columnar grain growth induced surface roughness.

True atomic layer growth is possible through molecular beam epitaxy (MBE); however, the range of materials that can be deposited using MBE is limited and MBE is a prohibitively expensive process. Another option is atomic layer deposition (ALD), used primarily in the semiconductor industry. Unlike MBE, which is a direct deposition method, ALD is a reactive deposition method. For some materials ALD requires a water precursor, which can be destructive to device materials and/or properties, especially in materials that are susceptible to corrosion, such as the materials in a TMR junction. Currently, the state of the art for engineering the electrical states at an interface is with hydrogen passivation in semi-conductors.

The methods described above modify the entire interface surface as opposed to modifying the interface surface only in selected areas and not modifying interface surface in other non-selected areas as part of an insitu process. Presently, site specific modification of an interface surface requires photolithographic or nano-imprinting processes and those processes can require several processing steps with each step having a potential to introduce a yield limiting defect.

Consequently, there exists a need for a method of engineering a property of an interface that provides for a precise manipulation of interface properties and precise location of interface manipulation. There is also a need for a method of engineering a property of an interface that provides for a controllable and uniform deposition on an interface surface of any of a variety of elements that can be obtained from a metal-organic precursor.

### SUMMARY OF THE INVENTION

The present invention solves the aforementioned problems associated with manipulating the properties of an interface surface by combining a gas cluster ion beam apparatus (GCIB) with a source that generates a metal-organic gas that includes one or more metal-organic compounds. The metal-organic gas is combined in a carrier gas to form a composite gas that includes the metal-organic compounds. The composite gas is processed by the GCIB (e.g. is clustered, ionized, and accelerated) and is targeted at an interface surface of a target material so that at least a portion of the metal-organic compounds remain in contact with the interface surface.

A method of engineering a property of an interface using a gas cluster ion beam apparatus includes generating a metal-organic gas that includes at least one metal-organic compound, forming a composite gas by combining the metal-organic gas with a carrier gas in the GCIB, and forming a beam comprising a plurality of gas clusters from the composite gas so that the gas clusters includes the metal-organic compounds. The beam of gas cluster is ionized to form a beam of gas cluster ions which are accelerated by the GCIB. The beam irradiates an interface surface of a target material so that the gas cluster ions impact on the interface surface and disintegrate upon impact with the interface surface. The impact results in at least a portion of the metal-organic compound remaining in contact with the interface surface.

Beneficial properties of an interface surface that can be engineered by the method include but are not limited to a change in an index of refraction, passivation of dangling chemical bonds, tunning of a stress condition, enhancing of an adhesion of the interface surface, polarization of the interface surface, and planar doping of the interface surface.

Other aspects and advantages of the present invention will become apparent from the following detailed description, taken in conjunction with the accompanying drawings, illustrating by way of example the principles of the present invention.

### BRIEF DESCRIPTION OF THE DRAWINGS

FIG. 1 depicts a flow diagram of a method of engineering a property of an interface using a gas cluster ion beam apparatus.

FIG. 2 is a cross-sectional view depicting an example of a generator for generating a metal-organic gas that is combined with a carrier gas to form a composite carrier gas.

FIG. 3 is cross-sectional view depicting a gas cluster ion beam apparatus and an interface surface of a target material that is irradiated by a beam of gas cluster ions that includes at least one metal-organic compound.

FIGS. 4a and 4b are cross-sectional views depicting an irradiating of an interface surface by a beam of gas cluster ions that include at least one metal-organic compound.

FIG. 5a is a cross-sectional view depicting a target material and an interface surface of the target material.

FIG. 5b is an enlarged cross-sectional view of a section I-I of FIG. 5a and depicts a metal-organic compound in contact with an interface surface.

FIG. 5c is a cross-sectional view depicting a target material formed on a prior layer of material.

FIG. 5d is a cross-sectional view depicting a target material including an interface surface with an initial surface roughness.

FIG. 5e is a cross-sectional view depicting a reduced surface roughness in the interface surface of the target material of FIG. 5d after a smoothing process.

FIG. 6 is a top plan view depicting examples of a relative motion between a beam of gas cluster ions and a target material.

FIG. 7a is a top plan view depicting a mask layer positioned over an interface surface of a target material.

FIGS. 7b and 7c are cross-sectional views of a mask layer in contact with an interface surface and a mask layer positioned adjacent to an interface surface respectively.

FIG. 8 is a top plan view of a predetermined site on an interface surface that is targeted by a beam of gas cluster ions.

FIG. 9 is a schematic depicting an example of a plurality of metal-organic generators for generating a plurality of different metal-organic compounds.

FIG. 10 is a timing diagram depicting a selecting of one or more metal-organic gasses to be combined with a carrier gas in a gas cluster ion beam apparatus.

FIG. 11 is a diagram depicting a system for engineering a property of an interface.

### DETAILED DESCRIPTION

In the following detailed description and in the several figures of the drawings, like elements are identified with like reference numerals.

As shown in the drawings for purpose of illustration, the present invention is embodied in a method of engineering a property of an interface using a gas cluster ion beam apparatus. The method includes generating a metal-organic gas that includes at least one metal-organic compound, forming a composite gas by combining the metal-organic gas with a carrier gas and communicating the composite gas to the gas cluster ion beam apparatus, and forming a beam comprising a plurality of gas clusters from the composite gas. The gas clusters are ionized to form a beam of gas cluster ions that include the metal-organic compound. The gas cluster ions are accelerated and the beam irradiates an interface surface of a target material so that the gas cluster ions impact on the interface surface and disintegrate upon impact so that at least a portion of the metal-organic compound carried by the gas cluster ions remain in contact with the interface surface.

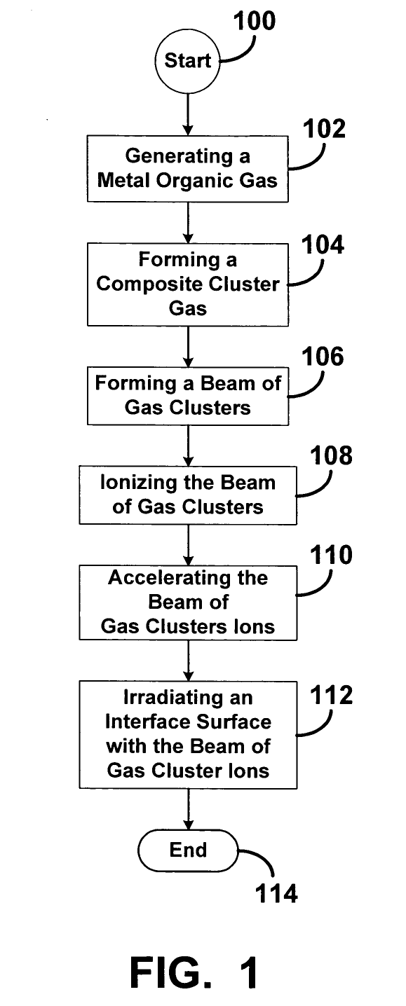

In FIG. 1, a method 100 of engineering a property of an interface using a gas cluster ion beam apparatus includes at a stage 102, generating a metal-organic gas that includes at least one metal-organic compound. Processes for generating the metal-organic gas are well understood in the microelectronics art and include but are not limited to using a metal-organic chemical vapor deposition (MOCVD) process to generate the metal-organic gas.

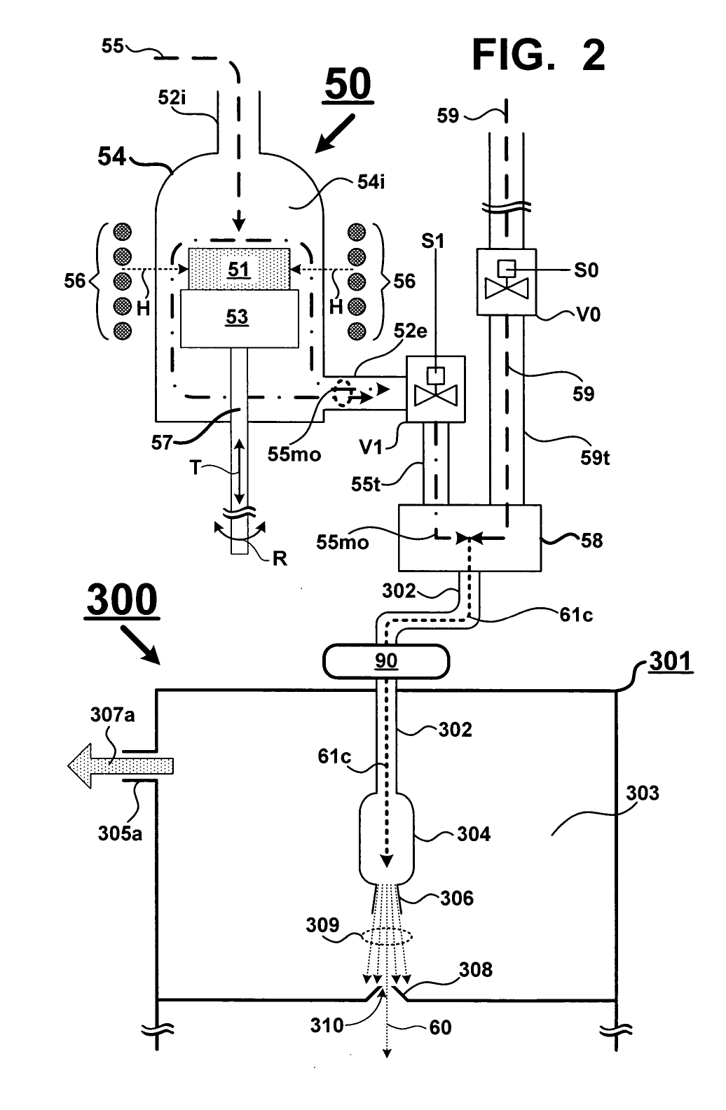

Referring to FIG. 2, as one example of how the metal-organic gas can be generated at the stage 102, a metal-organic generator 50 includes a reactor vessel 54 that includes a metal-organic source material 51 connected with a substrate 53 and positioned in an interior 54i of the reactor vessel 54. For example, the substrate 53 can be a platen upon which the metal-organic source material 51 is mounted. The metal-organic source material 51 includes at least one metal-organic compound. As one example, the metal-organic compound can include one or more elements selected from The Periodic Table of Elements. Generally, the metal-organic source material 51 can include any number of elements that are available as a metal-organic compound precursor. A gas inlet 52i is connected to a gas source (not shown) so that a gas 55 is communicated into the interior 54i. A heat source 56 is positioned in thermal communication with the reactor vessel 54 so that heat H generated by the heat source 56 heats up the metal-organic source material 51 as the gas 55 flows over the metal-organic source material 51. The heating H results in a dissociating of the metal-organic compounds carried by the metal-organic source material 51 into the gas 55. The dissociated metal-organic compounds are carried away by the gas 55 to form a metal-organic gas 55mo.

Those skilled in the microelectronics art will appreciate the heating H of the metal-organic source material 51 can be accomplished using a variety of methods including but not limited to the use of radio frequency coils (RF coils) as the heat source 56. The RF coils can be electrically connected with a RF power supply (not shown). During the heating H, a shaft 57 connected with the substrate 53 may optionally be used to rotate R and/or translate T the substrate 53 to effectuate the dissociation of the metal-organic compound into the gas 55 and to properly position the metal-organic source material 51 in a heat zone generated by the heat source 56. The metal-organic gas 55mo can exit the reactor vessel 54 through an exhaust port 52e. The metal-organic generator 50 can be like those used in a MOCVD apparatus, for example. However, other means can be used to generate the metal-organic gas 55mo and the present invention is not be construed as being limited to the examples set forth herein.

Returning to FIG. 1, at a stage 104, a composite gas 61c is formed by combining the metal-organic gas 55mo with a carrier gas 59. Typically, the carrier gas 59 is a condensible gas used by a gas cluster ion beam apparatus 300 (GCIB 300 hereinafter) to form a plurality of gas clusters. The carrier gas 59 is combined (e.g. mixed) with the metal-organic gas 55mo to form the composite gas 61c so that the metal-organic compounds carried by the metal-organic gas 55mo are included as metal-organic compounds in the gas cluster formed by the GCIB 300. The carrier gas 59 and the gas 55 can be identical gasses or they can be different gasses. The carrier gas 59 and the gas 55 can be supplied from the same gas source or from different gas sources. The carrier gas 59 can be a gas including but not limited to an inert gas, nitrogen (N), oxides of nitrogen, oxygen (O₂), carbon dioxide (CO₂), carbon monoxide (CO), xenon (Xe), hydrogen (H), fluorine (F), methane (CH₄), silane (SiH₄), sulfur hexafluoride (SF₆), and a fluorocarbon.

As one example of how the metal-organic gas 55mo can be combined with the carrier gas 59, in FIG. 2, the metal-organic gas 55mo and the carrier gas 59 are combined in a manifold 58 via tubes (55t, 59t) where the gasses mix together to form the composite gas 61c. Optionally, a series of valves V1 and V1 can be used to control the flow of the gasses (55mo, 59). The valves (V0, V1) can be manually actuated by a user, mechanically actuated or electrically actuated by a computer or a dedicated process controller, for example. For instances, the valves (V0, V1) can be electrically actuated via electrical signals (S0, S1) in electrical communication with a computer running a software program that controls the metal-organic generator 50 and/or the GCIB 300.

In FIG. 1, at a stage 106, a beam 60 comprising a plurality of gas cluster is formed from the composite gas 61c. The beam 60 includes the metal-organic compounds carried by the composite gas 61c. Turning to FIG. 2, as is well understood in the GCIB art, the GCIB 300 includes a gas source chamber 301 that includes a gas feed tube 302 connected with a stagnation chamber 304. The composite gas 61c enters the stagnation chamber 304 at a high pressure where it condenses and then adiabatically expands through an expansion nozzle 306 to form a plurality of gas clusters 309. The gas clusters 309 can include several to several thousand (e.g. >5000) weakly bound atoms and/or molecules. A majority of the gas clusters 309 are skimmed away by a skimmer 308 that includes a very small aperture 310. However, a core of the gas clusters 309 pass through the aperture 310 to form the beam 60 comprising the gas clusters 309. An interior 303 of the gas source chamber 301 should be maintained at level of vacuum (e.g. <10⁻³ torr) necessary for the generation of the beam 60. Accordingly, the gas source chamber 301 typically includes a fitting 305a connected with a vacuum source 307a (not shown) that maintains a precise vacuum in the interior 303.

The configuration depicted in FIG. 2 is only one example of how the metal-organic gas 55mo can be generated. Those skilled in the microelectronics art will appreciate that if the gas 55 and the carrier gas 59 are identical, then the manifold 58, the valve V0, and the tube 59t may be eliminated and the tube 55t can be connected with the gas feed tube 302. Consequently, the gas 55 serves as the carrier gas for the GCIB 300 and the composite gas 61c comprises the metal-organic compounds that are dissociated from the metal-organic source material 51 into the gas 55 to form the metal-organic gas 55mo. Therefore, if the gas 55 is used as the carrier gas, then the gas 55 should be a compressible gas that will form the gas clusters 309.

For some applications, it may be necessary to purify the metal-organic gas 55mo to remove one or more elements from the gas so that they are reduced in concentration or are not included in the composite gas 61c. To that end, a filter 90 can be used to remove or reduce the number of undesirable elements contained in the metal-organic gas 55mo. For example, the filter 90 can be a mass analyzer (e.g. such as the type used in mass spectrometry) that sorts species of elements based on a mass-to-charge ratio. Although depicted with a position that is in line with the gas feed tube 302, the filter 90 may also be placed in line with the exhaust port 52e or the tube 55t.

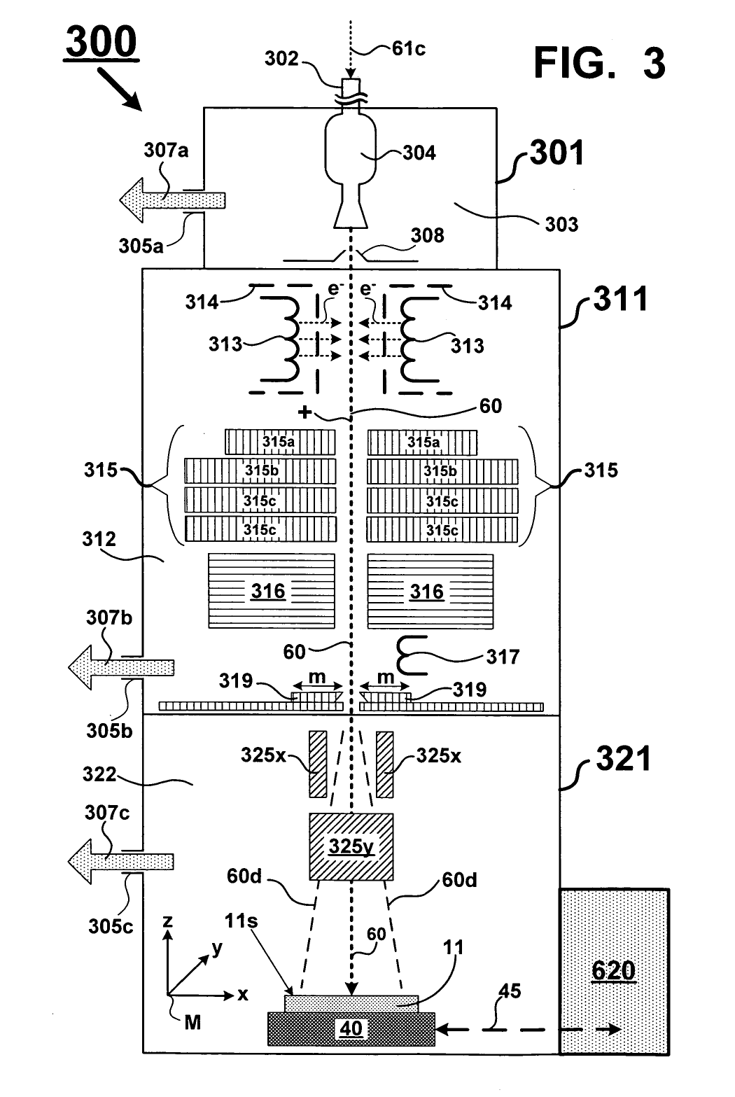

Turning to FIG. 3, at a stage 108, the beam 60 is ionized to impart a net charge (i.e. a positive “+” or a negative “−” charge) on each gas cluster 309 in the beam 60. As an example, the GCIB 300 can include an ionization chamber 311 that includes an ionization filament 313 for generating a stream of thermoelectrons e− that bombard the beam 60 resulting in electrons being ejected from the gas clusters 309 so that a net positive charge “+” is imparted to the gas clusters 309. An anode 314 is positioned adjacent to the filaments 313 and extracts the thermoelectrons e− from the filaments 313. The ionization filaments 313 and the anodes 314 can be connected with appropriate power supplies (not shown) to heat the ionization filaments 313 and to bias the anodes 314. A fitting 305b can be connected to a vacuum source 307b (not shown) that maintains a precise vacuum in an interior 312 of the ionization chamber 311.

At a stage 110, the beam 60 is accelerated to increase a momentum of the gas clusters 309. The GCIB 300 can include an acceleration section 315 that includes a plurality of high voltage electrodes that are connected with appropriate high voltage power supplies (not shown) and operative to accelerate and focus the beam 60. For example, the acceleration section 315 can include an extraction electrode 315a for extracting ions from the ionization region of the ionization filaments 313, an accelerator electrode 315b for accelerating the beam 60 to an energy level in the keV range, and one or more lens electrodes 315c for electrostatically focusing the beam 60 so the beam 60 is collimated and follows a predictable trajectory through the GCIB 300 towards an interface surface of a target material as will be described below.

Optionally, the GCIB 300 may also include: a magnetic filter 316 for deflecting light monomer ions and dimers out of the beam 60 while not deflecting the heavier gas cluster ions 309 that include the metal-organic compounds; a neutralizing filament 317 to inject low energy electrons into the beam 60 to prevent an excess positive charge build up on the target material/substrate during processing of the interface surface; and a shutter 319 that can be moved m to a blocking position to block the beam 60 during processing of the interface surface.

At a stage 112, the beam 60 passes into a processing section 321 of the GCIB 300 and irradiates an interface surface 11s of a target material 11 so that the gas cluster ions 309 impact on the interface surface 11s and disintegrate upon impact with the interface surface 11s. Upon impact, at least a portion of the metal-organic compound contained in the gas cluster ions 309 remain in contact with the interface surface 11s. The target material 11 can be connected with a substrate 40 that supports and securely holds the target material 11 during processing of the interface surface 11s. For example, the substrate 40 can be a vacuum chuck, a platen, a motion controlled x-y-z stage, or the like. The processing section 321 may include a pair of electrostatic deflection electrodes (325x, 325y) for deflecting 60d the beam 60 along a plane (e.g. a x-y plane) during processing of the interface surface 11s and to scan the beam 60 over the interface surface 11s. As was mentioned above, the processing section 321 can include a fitting 305c that is connected to a vacuum source 307c (not shown). As will be described below in greater detail, a motion M of the substrate 40 can be used to move the substrate 40 relative to the beam 60 during the irradiating at the stage 112 as depicted by a x-y-z axis. The motion M can include rotational, translational, and angular movements of the substrate 40.

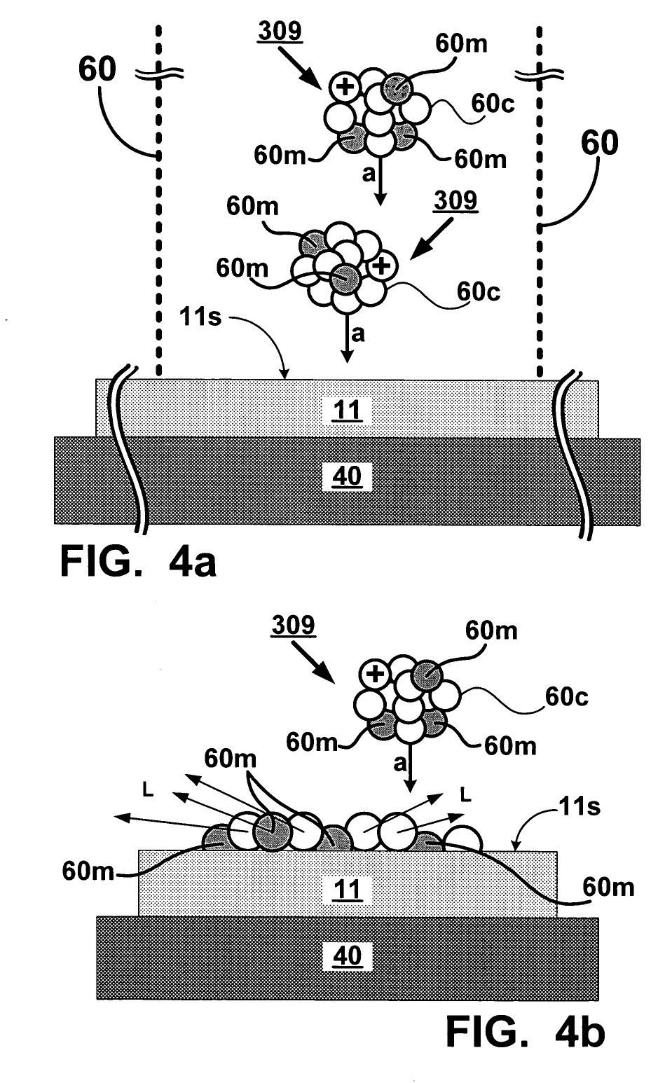

Referring to FIG. 4a, the beam 60 (denoted by heavy dashed lines) comprises a plurality of ionized gas clusters 309 that have a net positive + charge. Although not shown, the net charge can also be negative −. The ionized gas clusters 309 are depicted just prior to their impact on the interface surface 11s with each gas cluster 309 moving in a direction substantially towards the interface surface 11s as depicted by an arrow a. Each ionized gas clusters 309 includes atoms or molecules 60c that are determined by the carrier gas 59 and atoms or molecules of at least one metal-organic compound 60m as determined by the metal-organic gas 55mo.

In FIG. 4b, upon impact with the interface surface 11s, the ionized gas clusters 309 disintegrate with a portion of the weakly bound atoms/molecules deflecting off of the interface surface 11s as depicted by arrows L. A portion of the weakly bound atoms/molecules remain in contact with the interface surface 11s. Accordingly, at least a portion of the metal-organic compounds 60m carried by the ionized gas clusters 309 remain in contact with the interface surface 11s after the impact. The effect of the impact of the ionized gas clusters 309 on the interface surface 11s will depend in part on an acceleration voltage used to accelerate the ionized gas clusters 309, the mass of the ionized gas clusters 309, and the makeup of the constituent atoms and/or molecules that comprise the ionized gas clusters 309. Consequently, the interface surface 11s may only include an uppermost surface of the target material 11 or the interface surface 11s can include the uppermost surface and a very shallow region positioned below the uppermost surface.

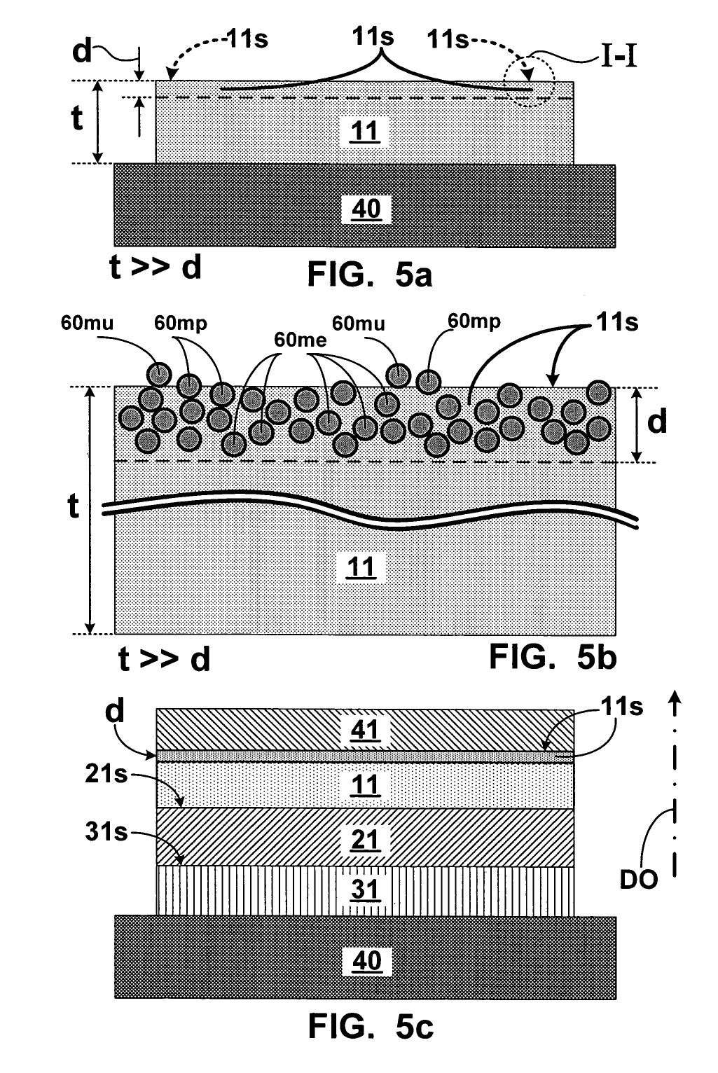

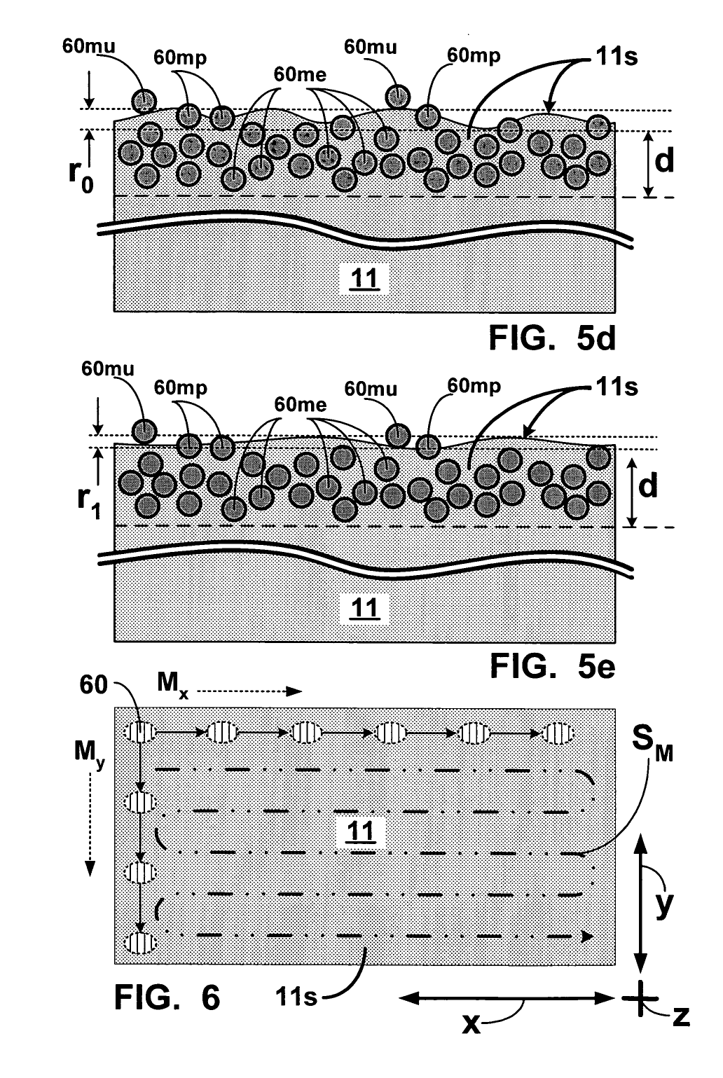

Therefore, in FIG. 5a, the interface surface 11s comprises at least an uppermost surface (see heavy dashed arrow 11s) of the target material 11 and the interface surface 11s may also include a shallow portion (see heavy solid lines for 11s) of the target material 11 that is positioned a predetermined distance d below the uppermost surface. The predetermined distance d is much less than a thickness t of the target material 11 (i.e. t>>d). As an example, if thickness t is 100 nm, then the predetermined distance d can be about 15 Å(i.e. 1.5 nm). The actual value of the predetermined distance d will be application specific. To effectuate a desired change in a property of the interface surface 11s, the predetermined distance d need not be very large. For example, the predetermined distance d can be in a range from about 10 Å to about 120 Å. The predetermined distance d can be measured in monolayers (e.g. ≧1.0 monolayer) or in sub-monolayers (e.g. <1.0 monolayer) and will depend on the material and composition of the target material 11, the materials selected for the metal-organic compounds 60m, the parameters of the GCIB 300 (e.g. acceleration voltage), and the length of bonds between the atoms of the target material 11 and the metal-organic compounds 60m. As another example, the predetermined distance d can be in a range from about 1.0 monolayer to about 20 monolayers.

A dashed line section I-I of FIG. 5a is depicted in greater detail in FIG. 5b and illustrates a position of the metal-organic compounds 60m relative to the interface surface 11s. The metal-organic compounds 60m may be distributed throughout the interface surface 11s in proportions that vary. A portion of the metal-organic compounds 60m can be positioned on the interface surface 11s as denoted by metal-organic compounds 60mu (i.e. they are positioned on the uppermost surface). Another portion of the metal-organic compounds 60m can be positioned partially in the interface surface 11s as denoted by metal-organic compounds 60 mp. Yet another portion of metal-organic compounds 60m can be positioned entirely within the interface surface 11s as denoted by metal-organic compounds 60me (i.e. they are disposed entirely within the interface surface 11s). Therefore, a contact of the metal-organic compounds 60m wit the interface surface 11s comprises any of the configurations depicted in FIG. 5b. That is, the metal-organic compounds 60mu may be positioned on the interface surface 11s, the metal-organic compounds 60mu may be positioned partially inward of the interface surface 11s, and the metal-organic compounds 60me may be positioned entirely within the interface surface 11s.

The target material 11 need not be in direct contact with the substrate 40. Moreover, the target material 11 can be one of a plurality of layers of material that are carried by the substrate 40. As an example, in FIG. 5c, the target material 11 can be formed (i.e. deposited, sputtered, etc.) on a prior layer 21 which in turn is formed on a prior layer 31. The layer 31 can be a semiconductor substrate (e.g. silicon —Si) and the layer 21 can be a layer of material (e.g tantalum —Ta) that was deposited on the layer 31, for example. The method 100 may optionally be applied to the interface surfaces (21s, 31s) of the layers (21, 31) to engineer a property of those interface surfaces.

As one example, the layers of material (21, 11) can be deposited on the layer 31 in a deposition order DO as part of manufacturing process. The layer 31 can be mounted on the substrate 40 through a load lock 620 connected with the processing section 321 of the GCIB 300. The load lock 620 may also be connected with a processing unit (not shown) for performing some other step in the manufacturing process, such as a deposition of a layer of material, for example. After a layer of material is deposited, that layer may subsequently be processed by the GCIB 300 according to the method 100. A plurality of the layers 31 can be carried by a wafer cassette, for example. Individual layers 31 can be removed from the wafer cassette by a robotic arm or the like and then transported between the GCIB 300 and the processing unit via the load lock 620.

As another example, the layer 31 can have one or more layers of material deposited on it in the deposition order DO and any layer requiring engineering of its interface surface is removed from the wafer cassette and is loaded onto the substrate 40 for processing by the GCIB 300 according to the method 100. After an interface surface of the layer is processed by the GCIB 300, a subsequent layer of material may then be deposited or otherwise formed on the interface surface by transporting the layer 31 to the processing unit via the load lock 620. For example, in FIG. 5c, after the interface surface 11s was processed by the GCIB 300 according to the method 100, a layer 41 is subsequently formed on the interface surface 11s.

The interface surface 11s need not be a substantially planar surface (i.e. flat) as depicted in FIG. 5b. For example, in FIG. 5d, a topography of the interface surface 11s may include an initial surface roughness r₀ as depicted by variations in surface height (i.e. undulations) on the interface surface 11s. The surface roughness r₀ can be measured as a RMS surface roughness. Because the interface surface 11s is not flat, a uniform irradiation of the interface surface with the metal-organic compounds 60m may not be possible. Accordingly, the interface surface 11s can be planarized prior to being processed by the GCIB 300 at the stage 112 using a process such as chemical mechanical planarization (CMP), for example. Alternatively, the GCIB 300 can be used to perform a surface smoothing irradiation process on the interface surface 11s to reduce the surface roughness r₀ prior to the stage 112. For instance, in FIG. 2, the valve V1 can be closed to cut off the flow of the metal-organic gas 55mo to the manifold 58. The valve V0 is opened to allow only the carrier gas 59 to flow into the stagnation chamber 304 so that the gas cluster ions 309 in the beam 60 are used for smoothing the interface surface 11s. The process of using a GCIB for surface smoothing are well understood in the microelectronics art and good literature exists on GCIB surface smoothing.

After the surface smoothing process, in FIG. 5e, a surface roughness r₁ of the interface surface 11s is reduced (i.e. r₁<r₀). Subsequently, the irradiation at the stage 112 can proceed using the composite gas 61c to effectuate the bombardment of the interface surface 11s with the metal-organic compounds 60m. Smoothing of the interface surface 11s can occur simultaneously with the irradiating at the stage 112 because the impact of the gas cluster ions 309 on the interface surface 11s can result in the aforementioned surface smoothing. The extent to which the initial surface roughness r₀ is reduced to the surface roughness r₁ by the irradiating at the stage 112 will depend on several factors including but not limited to a mass and a momentum of the gas cluster ions 309. Process parameters of the GCIB 300 (e.g. acceleration voltage) can be controlled to cause surface smoothing or to prevent surface smoothing during the irradiating at the stage 112.

During the irradiating at the stage 112, it may be desirable to target the beam 60 over the entirety of the interface surface 11s or over a only a portion of the interface surface 11s. In FIG. 6, the target material 11 can be moved relative to the beam 60 (i.e. the beam 60 is held stationary) during the irradiating at the stage 112 so that the beam 60 irradiates some or all of the interface surface 11s. The substrate 40 can be connected with a mechanical or an electrical-mechanical means for moving the substrate 40 during the irradiating at the stage 112. As one example, the substrate 40 can be connected with a precision motioned controlled x-y-z stage that is controlled by a computer or a dedicated control unit. The substrate 40 can be moved in a x-direction denoted by a dashed arrow Mₓ or in a y-direction as denoted by a dashed arrow M_{y}. Consequently, the interface surface 11s is moved relative to the beam 60. As another example, a micrometer stage connected with the substrate 40 can be used to impart motion (see M in FIG. 3) along any selected axes of motion such as along the x-y-z axes depicted in FIGS. 3 and 6 (note: in FIG. 6, the z axis is into the drawing sheet). The motion M can include rotation, linear translation, and tilting of the substrate 40. The motion M can also be used to effectuate the equivalent of a scanning motion by the beam 60 as depicted by a series of dashed lines S_{M}.

As was described above in reference to FIG. 3, the beam 60 can be moved while the substrate 40 is held stationary by electrostatically deflecting the beam 60 using the electrostatic deflection electrodes (325x, 325y). The deflection electrodes 325x can be used to move the beam 60 in the Mₓ direction along the x-axis X and the deflection electrodes 325y can be used to move the beam 60 in the M_{y} direction along the y-axis y. The electrostatic deflection electrodes (325x, 325y) can be used in combination to impart a motion that is a vector in the x-y plane. The electrostatic deflection electrodes (325x, 325y) may also be used to scan the beam 60 across the interface surface 11s while the substrate 40 is held stationary. For example, the beam 60 can be scanned S_{M} as depicted in FIG. 6. Scanning of the beam 60 includes a raster scanning. Because a range of beam deflection provided by the deflection electrodes (325x, 325y) may be to small to cover the entire interface surface 11s, it may be necessary to move both the beam 60 and the substrate 40 to cover the entire interface surface 11s. Accordingly, one skilled in the art will appreciate that the beam 60 and the interface surface 11s can be moved M relative to each other by applying the above describe motions to both the beam 60 and the substrate 40 at the same time. Furthermore, if the beam 60 has a small beam width, then the beam 60 can be scanned or raster scanned while the substrate 40 is in motion so that a larger area of the interface surface is irradiated during the stage 112.

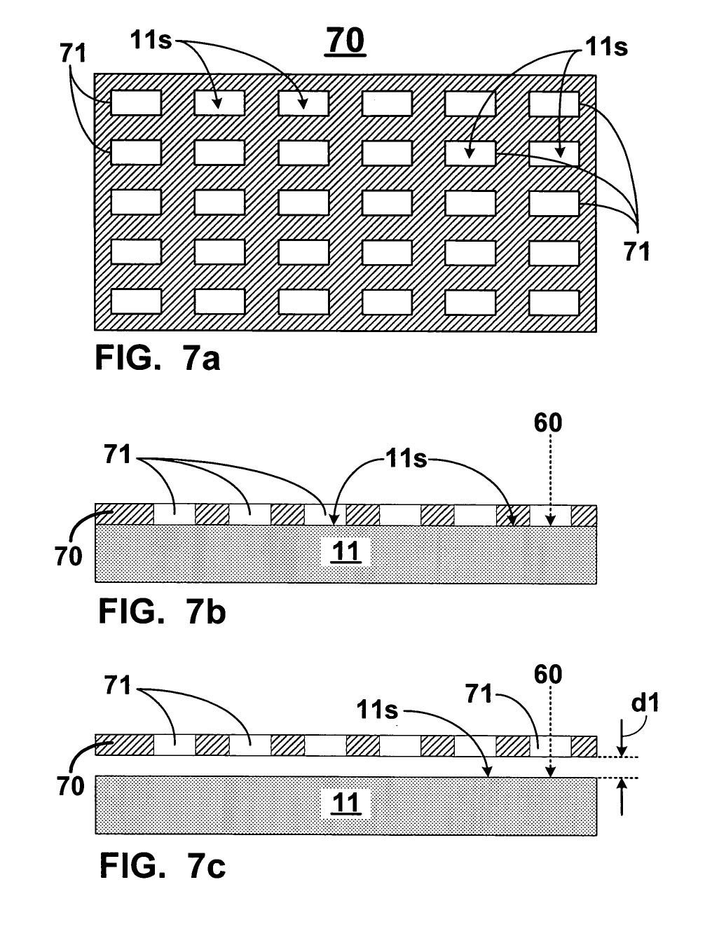

In some applications it may be desirable to control which areas on the interface surface 11s are irradiated by the beam 60. In FIGS. 7a, 7b, and 7c, a mask layer 70 including one or more apertures can be positioned over the interface 11s. The apertures 71 are through holes that extend all the way through the mask layer 70 so that the beam 60 passes through the apertures 71 and the gas cluster ions 309 impact on those portions of the interface surface 11s that are exposed by the apertures 71. The mask layer 70 may be positioned in contact with the interface surface 11s as depicted in FIG. 7b or the mask layer 70 may be positioned over the interface surface 11s and separated by a distance d1 as depicted in FIG. 7c. Preferably, the distance d1 is as small as possible to prevent the beam 60 from straying outside the bounds defined by the apertures 71. The mask layer 70 can be made from any material that can be patterned including but not limited to a material that can be lithographically patterned and etched using processes that are well understood in the microelectronics art. The mask layer 70 can be deposited on the interface surface 11s using well known semiconductor processing techniques and then lithographically patterned and etched to form the apertures 71. For example, the mask layer can be a photoresist material that is spin deposited on the interface surface 11s. The actual shape of the apertures 71 will be application dependent and need not be rectangular as depicted in FIG. 7a.

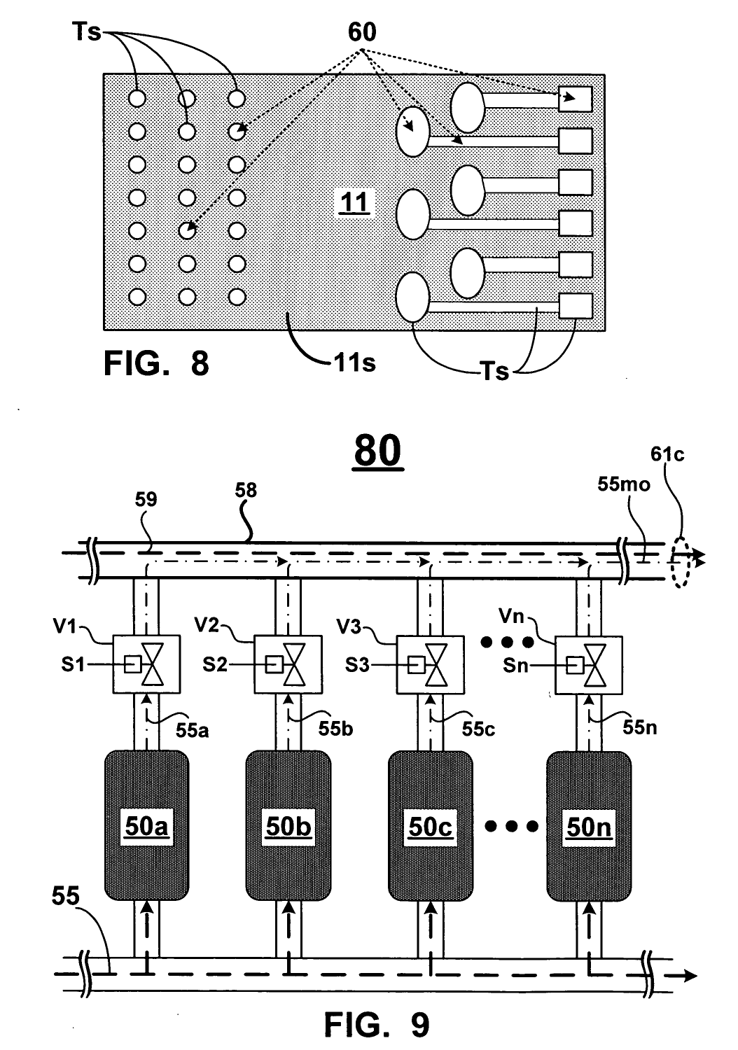

In FIG. 8, the beam 60 is targeted at one or more specific sites Ts on the interface surface 11s so that a property of the interface surface 11s at the specific sites Ts is effected by the metal-organic compounds 60m. Therefore, the irradiating at the stage 112 is controlled so that the beam 60 irradiates the interface surface 11s only at the specific sites Ts. The aforementioned moving M of the beam 60, the interface surface 11s, or both the beam 60 and the interface surface 11s can be used to target the specific sites Ts. A computer program (e.g. a CAD program) can be used to control the moving M in the GCIB 300 and to determine a shape of the specific sites Ts as irradiated (e.g. as painted) on the interface surface 11s. As an example, the specific sites Ts can have a circular shape or a complex shape as depicted in FIG. 8.

The composite gas 61c can include one or more metal-organic compounds that are carried by the metal-organic gas 55mo. During a course of the irradiating at the stage 112, it may be desirable to alter the metal-organic compounds 60m that are present in the gas cluster ions 309. In FIG. 9, in a multiple generator system 80, the gas 55 is supplied to metal-organic generators (50a, 50b, 50c, and 50n) each of which contains a different metal-organic source material 51. The generators (50a, 50b, 50c, and 50n) in the multiple generator system 80 may be like the metal-organic generator 50 depicted in FIG. 2. Valves (V1, V2, V3, and Vn) control a flow of metal-organic gasses (55a, 55b, 55c, 55n) that are generated by the metal-organic generators (50a, 50b, 50c, 50n). The flow of the gasses (55a, 55b, 55c, 55n) is controlled by signals (S1, S2, S3, Sn) which can open, close, or partially open/close their respective valves. A computer or dedicated control unit (not shown) can be used to control the generators and their respective valves. The gas flows (55a, 55b, 55c, and 55n) from the reactors are combined in a manifold 58 where they form the metal-organic gas 55mo that is subsequently mixed with the carrier gas 59 to form the composite gas 61c. As was described above in reference to FIG. 3, the composite gas 61c is supplied to a gas feed tube 302 in the gas source chamber 301 of the GCIB 300.

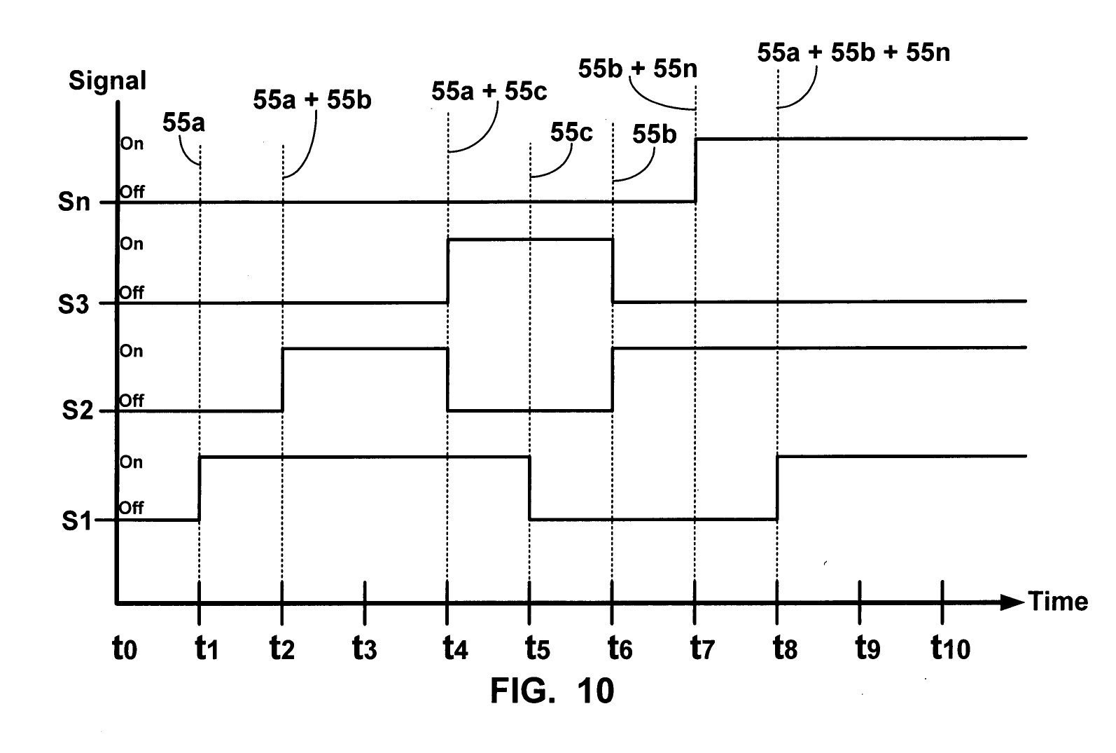

In FIG. 10, a timing diagram depicts Time on a x-axis and a state (i.e. “On” or “Off”) for the signals (S1, S2, S3, Sn) on a y-axis. The signals (S1, S2, S3, Sn) control valves (V1, V2, V3, Vn) as depicted in the multiple generator system 80 of FIG. 9. Therefore, if a signal is “On”, then the valve it controls is on and if a signal is “Off”, then the valve it controls is off. The composition of the metal-organic gas 55mo is determined by a combination of the metal-organic gasses (55a, 55b, 55c, 55n). From t0 to t2, the metal-organic gas 55mo comprises the metal-organic gas 55a from generator 50a. From t2 to t4, the metal-organic gas 55mo comprises the metal-organic gasses 55a and 55b from generators 50a and 50b. From t4 to t5, the metal-organic gas 55mo comprises the metal-organic gasses 55a and 55c from generators 50a and 50c. From t5 to t6, the metal-organic gas 55mo comprises the metal-organic gas 55c from generator 50c. From t6 to t7, the metal-organic gas 55mo comprises the metal-organic gas 55b from generator 50b. From t7 to t8, the metal-organic gas 55mo comprises the metal-organic gasses 55b and 55n from generators 50b and 50n. Finally, from t8 onward, the metal-organic gas 55mo comprises the metal-organic gasses 55a, 55b, and 55n from generators 50a, 50b, and 50n.

Accordingly, during the course of the irradiating at the stage 112, the beam 60 will contain different metal-organic compounds 60m and different combinations of metal-organic compounds 60m. The units of Time in FIG. 10 will be application specific and could be in units of seconds, minutes, or hours, for example. The signals (S1, S2, S3, Sn) may cause the valves (V1, V2, V3, Vn) to fully open and fully close or the signals may cause the valves to partially open/close so that a flow rate of the metal-organic gasses (55a, 55b, 55c, 55n) from the generators is either increased or decreased by the signals.

The configuration depicted in FIGS. 2 and 9 can also be used to modulate a concentration of the metal-organic compound 60m that is in contact with the interface surface 11s. The valves (V0, V1, V2, V3, Vn) and the signals (S0, S1, S2, S3, Sn) can be used to control gas flow rates and/or a mixing ratio of the metal-organic gas 55mo with the carrier gas 59 to increase or to decrease a concentration of the metal-organic compound 60m in the metal-organic gas 55mo. The heat H applied to the metal-organic source material 51 can also be increased or decreased to increase or decrease the rate at which the metal-organic compound 60m contained in the metal-organic source material 51 dissociate into the gas 55.

User controllable parameters for the GCIB 300 can be used to affect one or more properties of the gas cluster ions 309 in the beam 60. As one example, in FIG. 3, the ionization filaments 313 in the ionization chamber 311 can be used to increase an ionization state of the gas cluster ions 309 during the ionizing at the stage 108. By increasing the ionization state of the gas cluster ions 309, a chemical reactivity of the metal-organic compound 60m with the interface surface 11s can be increased. As a second example of how a user controllable parameter of the GCIB 300 can be used to affect a property of the gas cluster ions 309, an acceleration voltage applied to the high voltage electrodes of the acceleration section 315 can be increased to increase an acceleration of the gas cluster ions 309 thereby increasing a momentum of the gas cluster ions 309. The increased momentum can be used to control the predetermined depth d at which the metal-organic compounds 60m are positioned in the interface surface 11s. As a third example, the irradiating at the stage 112 can be continued until a desired concentration of the metal-organic compound 60m is in contact with the interface surface 11s. For instance, the beam 60 can be held stationary at a desired site on the interface surface 11s until the desired concentration of the metal-organic compound 60m is obtained at the site. The beam 60 may also be repeatedly scanned over the interface surface 11s until the desired concentration of the metal-organic compound 60m is obtained. Another parameter that may be controlled to obtain the desired concentration of the metal-organic compound 60m is irradiation time during the irradiating at the stage 112.

One advantage to the method 100 is that the contact of the metal-organic compound 60m with the interface surface 11s can result in a chemical reaction between metal-organic compound 60m and the target material 11. The effect of the chemical reaction will be substantially contained within a region defined by the interface surface 11s (see FIG. 5b) so that the chemical reaction changes a property of the interface surface 11s without changing a property of the entire target material 11.

The property that is changed will be application specific and will depend in part on the target material 11 and the metal-organic compounds 60m that are in contact with the interface surface 11s. Moreover, environmental conditions in the processing section 321 can also effect the chemical reaction. For example, the substrate 40 and/or the processing section 321 can be heated or cooled to effect a temperature of the target material 11 that in turn effects the chemical reaction.

Examples of properties of the interface surface 11s that can be changed by the chemical reaction include but are not limited to a change in an index of refraction of the interface surface 11s, a passivation of dangling bonds in the interface surfaces 11s, a tunning of a stress condition in the interface surfaces 11s, an enhancing of a cohesion of the interface surface 11s with a subsequent layer of material to be deposited on the interface surface 11s (see layer 41 in FIG. 5c), a polarization of the interface surface 11s, and a planar doping of the interface surface 11s.

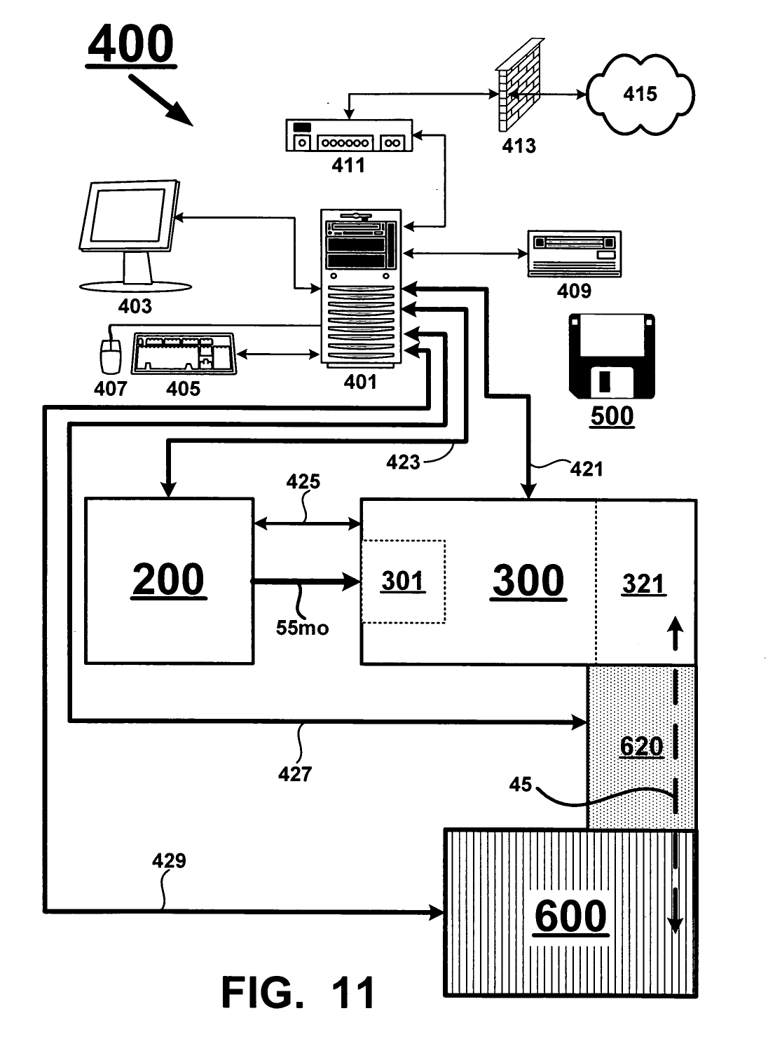

In FIG. 11, a system 400 for engineering a property of an interface using a gas cluster ion beam apparatus includes a metal-organic generator 200 that is connected with the gas cluster ion beam apparatus 300. The metal-organic generator 200 generates a metal-organic gas 55mo that includes at least one metal-organic compound 60m. The metal-organic generator 200 can include one or more generators as was described above in reference to FIGS. 2 and 9. The metal-organic gas 55mo is supplied to the gas source chamber 301 of the GCIB 300. As was described above, the metal-organic gas 55mo can be mixed with a carrier gas 59 to form a composite gas 61c that is used to form the beam 60 of gas cluster ions 309.

The system 400 can also include a controller 401 for controlling the GCIB 300 and the metal-organic generator 200. The controller 401 can be a general purpose computer, a work station, server, a laptop PC, or a dedicated process controller, for example. A commercially available GCIB apparatus 300 may already include a controller 401 that can be used to control the GCIB 300 and the metal-organic generator 200. If necessary, the system 400 may also include input devices such as a keyboard 405, a mouse 407, a display 403, and one or more peripheral devices 409 that are connected with the controller 401. Additionally, the system 400 can include a networking device 411 (e.g. a LAN device) that can be hardwired or wirelessly connected with the controller 401. The networking device 411 may also allow the controller to communicate with an internal network (e.g. an Intranet) or to communicate with an external network such as the Internet 415. A firewall 413 may also be used to provide secure communications between the controller 401 and the Internet 415. The controller 401 can communicate with and control the GCIB 300 and the metal-organic generator 200 via control signals 421 and 423 respectively. The GCIB 300 and the metal-organic generator 200 may also include a communications link 425 that allows data and control signals to be communicated between them. The keyboard 405, mouse 407, and the display 407 can be used to monitor, stop, start, or modify the processing of an interface surface 11s by the system 400.

Control of the GCIB 300 and the metal-organic generator 200 by the controller 401 can be by a computer program or an algorithm fixed in a computer readable media 500. The computer readable media 500 can include data and instructions that implement the method 100 of FIG. 1. Although the computer readable media 500 is depicted as a floppy disc, the computer readable media 500 can be any media in which program instructions and data can be fixed and includes but is not limited to optical storage media, magnetic storage media, and solid state memory media. The solid state memory media includes but is not limited to MRAM, SRAM, DRAM, ROM, and flash memory, just to name a few. The computer readable media 500 may be contained within the controller 401 or may be communicated to the controller 401 via a peripheral device 409, the Internet 415, or an local network such as an Intranet. For example, a hard drive in the controller 401 can be the media 500 or an optical disk drive 409 can include an optical disk as the media 500. A suitable programming language including but not limited to C, C++, and JAVA™ can be used to program the instructions that are fixed in the media 500.

The system 400 can also include at least one processing unit 600 that can be connected with the GCIB 300. For instance, the load lock 620 may be used to connect the processing unit 600 with the GCIB 300. Signals (421, 423, 425, 427, 429) from the controller 401 can be used to control and coordinate processing between the GCIB 300, the metal-organic generator 200, the processing unit 600, and the load lock 620. The load lock 620 can be used to transport a work piece (e.g. the target material 11 and its interface surface 11s) back and forth between the GCIB 300 and the processing unit 600. For example, the processing unit 600 can be a deposition apparatus for depositing one or more layers of material. The layer of material deposited can be the target material 11 and after the deposition the target material 11 can be moved from the processing unit 600 to the GCIB 300 via the load lock 620 so that the interface surface 11s of the target material 11 can be irradiated. The target material 11 can then be moved back to the processing unit 600 for a deposition of new layer of material on the interface surface 11s. After a deposition of the new layer of material in the processing unit 600, the interface surface of the new layer can optionally be moved to the GCIB 300 to have the interface layer irradiated.

Although several embodiments of the present invention have been disclosed and illustrated, the invention is not limited to the specific forms or arrangements of parts so described and illustrated. The invention is only limited by the claims.

What is claimed is:

1. A method of engineering a property of an interface using a gas cluster ion beam apparatus, comprising:
generating a metal-organic gas including at least one metal-organic compound;
forming a composite gas by combining the metal-organic gas with a carrier gas;
forming a beam comprising a plurality of gas clusters from the composite gas;
ionizing the gas clusters to form gas cluster ions;
accelerating the gas cluster ions; and
irradiating an interface surface of a target material with the beam so that the gas cluster ions impact on the interface surface, disintegrate upon impact, and at least a portion of the metal-organic compound remains in contact with the interface surface.

2. The method as set forth in claim 1, wherein the carrier gas comprises a gas selected from the group consisting of an inert gas, nitrogen, oxides of nitrogen, oxygen, carbon dioxide, hydrogen, fluorine, methane, silane, sulfur hexafluoride, carbon monoxide, xenon, and a fluorocarbon.

3. The method as set forth in claim 1, wherein a momentum of the gas cluster ions is increased by increasing an acceleration voltage of the gas cluster ion beam apparatus during the accelerating.

4. The method as set forth in claim 1 and further comprising:
increasing an ionization state of the gas cluster ions during the ionizing so that a chemical reactivity of the metal-organic compound with the interface surface is increased.

5. The method as set forth in claim 1, wherein at least a portion of the metal-organic compound is positioned inward of the interface surface by a predetermined depth.

6. The method as set forth in claim 5, wherein the predetermined depth is in a range from about 10 angstroms to about 120 angstroms.

7. The method as set forth in claim 5, wherein the predetermined depth is in a range selected from the group consisting of a range that is less than 1.0 monolayer and a range from about 1.0 monolayer to about 20 monolayers.

8. The method as set forth in claim 1, wherein at least a portion of the metal-organic compound includes a position selected from the group consisting of a position that is substantially on the interface surface, a position that is partially embedded in the interface surface, and a position that is entirely within the interface surface.

9. The method as set forth in claim 1 and further comprising:
selecting two or more different metal-organic compounds from a plurality of metal-organic generators so that the selected metal-organic compounds are included in the metal-organic gas during the generating.

10. The method as set forth in claim 1 and further comprising:
modulating a concentration of the metal-organic compound that is in contact with the interface surface by a selected one of increasing a concentration of the metal-organic compound in the metal-organic gas or decreasing a concentration of the metal-organic compound in the metal-organic gas.

11. The method as set forth in claim 1 and further comprising:
continuing the irradiating until a desired concentration of the metal-organic compound is in contact with the interface surface.

12. The method as set forth in claim 1, wherein the contact of the metal-organic compound with the interface surface results in a chemical reaction between the metal-organic compound and the target material.

13. The method as set forth in claim 12, wherein the chemical reaction changes a property of the interface surface selected from the group consisting of a change in an index of refraction of the interface surface, a passivation of dangling chemical bonds in the interface surface, a tunning of a stress condition in the interface surface, an enhancing of an adhesion of the interface surface with a subsequent layer of material to be deposited on the interface surface, a polarization of the interface surface, and a planar doping of the interface surface.

14. The method as set forth in claim 1 and further comprising during the irradiating:
moving a selected one of
the target material relative to the beam of gas cluster ions,
the beam of gas cluster ions relative to the target material, or
the beam of gas cluster ions and the target material relative to each other.

15. The method as set forth in claim 14, wherein the moving the beam of gas cluster ions relative to the target material comprises a scanning of the beam of gas cluster ions over the interface surface.

16. The method as set forth in claim 1 and further comprising:
a mask layer including at least one aperture, the mask layer is positioned over the interface surface, and wherein during the irradiating the beam of gas cluster ions pass through the aperture and impact on the interface surface.

17. The method as set forth in claim 16, wherein the mask layer is in contact with the interface surface.

18. The method as set forth in claim 1 and further comprising:
targeting the beam of gas cluster ions at one or more specific sites on the interface surface during the irradiating so that the gas cluster ions impact on the specific sites and the metal-organic compound remains in contact with the interface surface at the specific sites.

19. The method as set forth in claim 18 and further comprising during the targeting:
moving a selected one of
the target material relative to the beam of gas cluster ions,
the beam of gas cluster ions relative to the target material, or
the beam of gas cluster ions and the target material relative to each other, and
wherein the moving positions the predetermined site to receive the beam of gas cluster ions.

20. The method as set forth in claim 1, wherein the generating comprises heating the metal-organic compound so that the metal-organic compound dissociates.

21. The method as set forth in claim 1 and further comprising prior to the irradiating:
smoothing the interface surface to reduce a surface roughness of the interface surface.

22. The method as set forth in claim 1 and further comprising:
smoothing the interface surface during the irradiating to reduce a surface roughness of the interface surface.

23. An interface surface of a target material engineered according to the method as set forth in claim 1.

24. A computer readable media including program instructions for engineering a property of an interface using a gas cluster ion beam apparatus, comprising:
program instruction for generating a metal-organic gas including at least one metal-organic compound;
program instructions for forming a composite gas by combining the metal-organic gas with a carrier gas;
program instructions for forming a beam comprising a plurality of gas clusters from the composite gas;
program instructions for ionizing the gas clusters to form gas cluster ions;
program instructions for accelerating the gas cluster ions; and
program instructions for irradiating an interface surface of a target material with the beam so that the gas cluster ions impact on the interface surface, disintegrate upon impact, and at least a portion of the metal-organic compound remains in contact with the interface surface.

25. The computer readable media as set forth in claim 24 and further comprising:
program instructions for moving a selected one of the beam relative to the target material, the target material relative to the beam, or the beam and the target material relative to each other.

26. The computer readable media as set forth in claim 24 and further comprising:
program instructions for smoothing the interface surface at a selected one of prior to the irradiating or during the irradiating.

27. A system for engineering a property of an interface using a gas cluster ion beam apparatus, comprising:
a metal-organic generator operative to generate a metal-organic gas including at least one metal-organic compound,
the metal-organic generator is connected with the gas cluster ion beam apparatus so that the metal-organic gas is supplied to the gas cluster ion beam apparatus; and
a controller for controlling the metal-organic generator and the gas cluster ion beam apparatus, and
wherein the gas cluster ion beam apparatus is operative to generate a beam of gas cluster ions that include the metal-organic compound and to irradiate an interface surface of a target material with the beam of gas cluster ions so that the gas cluster ions impact on the interface surface, disintegrate upon impact, and at least a portion of the metal-organic compound remains in contact with the interface surface.

28. The system as set forth in claim 27 and further comprising:
a load lock connected with the gas cluster ion beam apparatus and operative to transport a work piece that includes the target material to and from the gas cluster ion beam apparatus.

29. The system as set forth in claim 27 and further comprising:
a processing unit connected with the gas cluster ion beam apparatus and operative to perform a process on the work piece.

30. The system as set forth in claim 29, wherein the processing unit is connected the load lock and the load lock transports the work piece between the gas cluster ion beam apparatus and the processing unit.
